(19) United States
(12) Patent Application Publication
(10) Pub. No.: US 2009/0014870 A1
(43) Pub. Date: Jan. 15, 2009

(54) SEMICONDUCTOR CHIP AND PACKAGE PROCESS FOR THE SAME

(75) Inventor: Ping-Chang Wu, Hsinchu County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/776,726

(22) Filed: Jul. 12, 2007

(51) Int. Cl. H01L 21/30; H01L 23/48

(52) U.S. Cl. 257/737; 438/458; 257/E29.111; 257/E21.506

(57) ABSTRACT

A semiconductor chip is provided. The semiconductor chip includes a chip and chip bump pads thereon. The chip bump pads include at least two chip bump pads that are physically connected.

### BACKGROUND OF THE INVENTION

1. Field of Invention

The present invention relates to an integrated circuit device and package process for the same; more particularly, the present invention relates to a semiconductor chip and package process for the same.

2. Description of Related Art

As electronic technology progresses, products that are humanized and with complicated functionalities are continuously being introduced to the market. For examples, the exterior appearance of an electronic product has been designed to be lighter, thinner, shorter and more compact. Therefore, in semiconductor package technology, many highly integrated semiconductor packages are being developed. For example, through the Chip Scale Package (CSP) technology, the above-mentioned requirements for an electronic product can be achieved, wherein the cross-sectional dimension of a finished package and the cross-sectional dimension of the chip are substantially the same. Hence, the dimension of a CSP is small and CSP technology is broadly used in semiconductor packaging.

Techniques for achieving chip scale package are multifold, and one type of which is the Wafer Level CSP technology. According to the Wafer Level CSP technology, the packaging and the testing are basically performed on the entire wafer first, followed by dicing the wafer into individual die. Since no wiring or underfilling processes are required in the Wafer Level CSP technology, the dimension of the wafer after packaging is the substantially the same as that of the die. Hence, according to the wafer level CSP technology, the IC can maintain its original dimension after packaging, which conforms to the demand for high level assembly of mobile information products. Further, in terms of electrical property standard, the chip can directly connect to the electrical circuit board via a shortest electrical route through tin balls. Hence, the speed for information transmission is greatly enhanced to effectively lower the probability of noise interference. Currently, the wafer level CSP technology is typically being applied to chips, logic/analog mix devices, electrical source control devices and various integrated passive devices of memory devices, integrated passive devices, analog devices, radio frequency devices, power amplifiers, voltage adjustment devices, PC devices, etc. of mobile communication devices, consumer electronics and portable products.

The wafer level CSP process includes forming a bump on each of a plurality of bump pads of the wafer. Thereafter, dicing of the wafer is conducted to form a flip chip package 100 as shown in FIG. 1A. Each flip chip package 100 includes a chip 110 and a plurality of bumps 130. The chip 110 includes a plurality of chip bump pads 114, configured on the active surface of the chip 110. The chip bump pads 114, which are not electrically connected to each other, are electrically connected to the devices 102 respectively on the chip 110 through an interconnect 124.

After forming the flip chip package 100, a reflow process is performed to connect the flip chip package 100 to a substrate 140. In general, the substrate 140 includes a plurality of bump pads 144 and a plurality of ball pads 148, respectively disposed on the upper surface 142 and the lower surface 146 of the substrate 140. During the reflow process, flux (not shown) is first applied. Through a heating process, the bump 130 of the flip chip package 100 is connected to the bump pad 144 of the substrate. Thereafter, the space between the flip chip package 100 and the substrate 140 is filled with an underfill to enclose the bumps 130.

Thereafter, a plurality of balls 160 are planted on the ball pads 148. Through the ball 160, the substrate 140 is electrically connected to the printed circuit board 170.

In the above Wafer Level CSP process, the devices in the chip 110 are respectively connected to the substrate 140 through a single chip bump pad 114 and a single bump 130. Hence, in the case that problems occur in the manufacturing process, electrical disconnection may result to lower the reliability of the product.

### SUMMARY OF THE INVENTION

The present invention is to provide a package process, wherein the reliability of the process is enhanced.

The present invention is to provide a semiconductor chip, wherein during the packing process, the reliability of the process is enhanced.

The present invention is to provide a semiconductor chip that includes a chip and a plurality of chip bump pads, wherein the chip bump pads are positioned on the chip and the chip bump pads include at least two chip bump pads that are physically connected.

In accordance to an embodiment of the present invention, in the above-mentioned semiconductor chip, the chip bump pads include a plurality of first chip bump pads configured in a peripheral region of the chip.

In accordance to an embodiment of the present invention, the above-mentioned at least two chip bump pads that are physically connected includes at least two of the first chip bump pads.

In accordance to an embodiment of the present invention, in the above semiconductor chip, the peripheral region includes multiples border regions and multiple corner regions, wherein the above-mentioned the two first chip bump pads that are physically connected are configured in the border regions, the corner regions or respectively in one of the border regions and in one of the corner regions.

In accordance to an embodiment of the present invention, in the above semiconductor chip, the chip bump pads includes a plurality of first wafer chip bump pads positioned in the peripheral region and a plurality of second chip bump pads positioned in the interior region.

In accordance to an embodiment of the present invention, in the above semiconductor chip, the above-mentioned at least two chip bump pads that are physically connected include at least two of the first chip bump pads.

In accordance to an embodiment of the present invention, in the above semiconductor chip, the peripheral region includes a plurality of border regions and a plurality of corner regions, wherein the above-mentioned two first chip bump pads that are physically connected are configured in the border regions, the corner regions or respectively in one of the border regions and in one of the corner regions.

In accordance to an embodiment of the present invention, in the above semiconductor chip, the above-mentioned at least two chip bump pads that are physically connected include at least two of the second wafer chip bump pads.

In accordance to an embodiment of the present invention, in the above semiconductor chip, the above-mentioned at least two chip bump pads that are physically connected include at least one of the first chip bump pads and at least one of the second chip bump pads.

In accordance to an embodiment of the present invention, in the above semiconductor chip, the chip bump pads are arranged in an array.

In accordance to an embodiment of the present invention, in the above semiconductor chip, the chip bump pads include three chip bump pads physically connected.

In accordance to an embodiment of the present invention, in the above semiconductor chip, the chip bump pads include more than three chip bump pads physically connected.

In accordance to an embodiment of the present invention, in the above semiconductor chip, the chip bump pads include a plurality of pairs of physically connected chip bump pads.

In accordance to an embodiment of the present invention, the above semiconductor chip further includes a plurality of metal interconnects respectively connected to the chip bump pads physically, wherein the two physically connected chip bump pads are physically connected through one of the metal interconnects.

The present invention provides a package process, wherein the process provides a flip chip package that includes a plurality of bumps, wherein the chips includes a plurality of chip bump pads, and the chip bump pads includes at least two chip bump pads that are physically connected, and bumps are configured on the bump pads. Further, the package process provides a substrate, and the first surface of the substrate comprises a plurality of bump pads, while the second surface of the substrate comprises a plurality of ball pads. Thereafter, the bumps of the flip chip package are physically connected to portions of the bumps on the substrate, wherein the two bump pads in the substrate corresponding to the physically connected two chip bumps is physically connected to one of the ball pads.

In accordance to an embodiment of the present invention, in the above package process, the fabrication process for the flip chip package includes wafer level CSP.

In accordance to an embodiment of the present invention, in the above Wafer Level CSP package process, a wafer is first provided, wherein the wafer includes a plurality of chips, and each chip includes a plurality of bump pads thereon. The bump pads include at least two bump pads that are physically connected. Thereafter, bumps are formed on the chip bump pads of the wafer. The wafer is subsequently diced to form a plurality of flip chip package unit.

In accordance to an embodiment of the present invention, in the above package process, the physically connected two chip bumps are physically connected through one of the plurality of metal interconnects that are underneath the bump pads.

In accordance to an embodiment of the present invention, in the above package process, the two bump pads in the substrate corresponding to the physically connected two chip bump pads are physically connected to one of the ball pads via one wiring between the bump pad of the substrate and the ball pad.

In accordance to an embodiment of the present invention, the above package process further includes forming a plurality of balls on the ball pads and the substrate is physically connected to a printed circuit board through the balls.

Since the devices on the chip are physically connected to the substrate through two or more of the bump pads and two or more of the bumps. Hence, chances that the devices are not electrically connected with the substrate through the bumps due to a failure of physically connection between the bumps and the bump pads are greatly reduced. Ultimately, the reliability of the final products is enhanced.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A to 1B are schematic, cross-sectional views showing selected process steps of Wafer Level CSP process according to the prior art.

FIGS. 2 to 5 are schematic, cross-sectional views showing selected process steps of Wafer Level CSP process according to an embodiment of the present invention.

FIGS. 2A to 2E are schematic, diagrams showing the arrangements of bump pads of a chip according to the present invention.

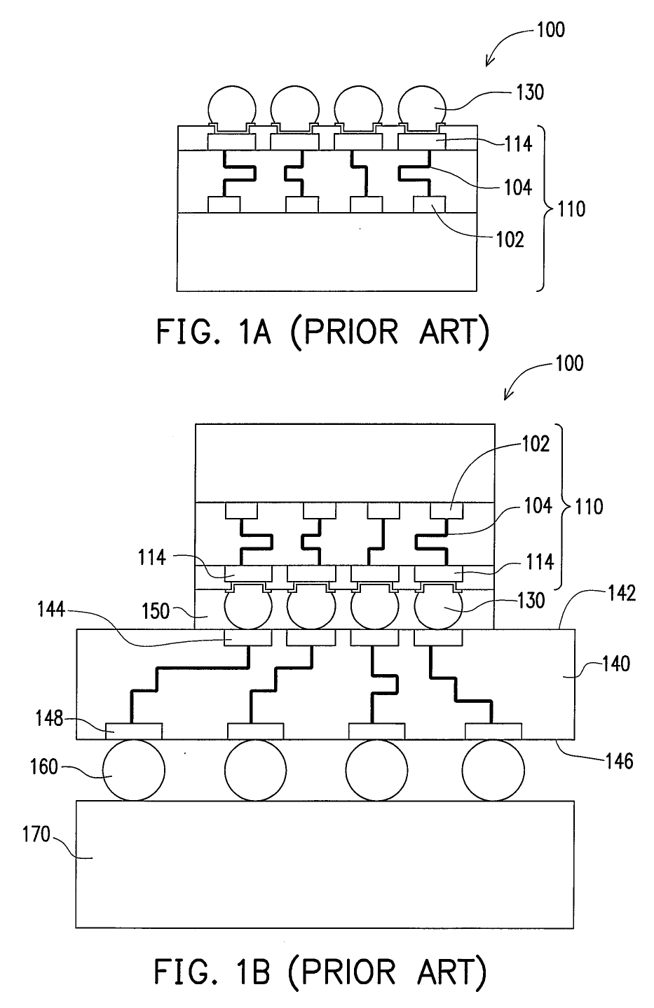

### DESCRIPTION OF EMBODIMENTS

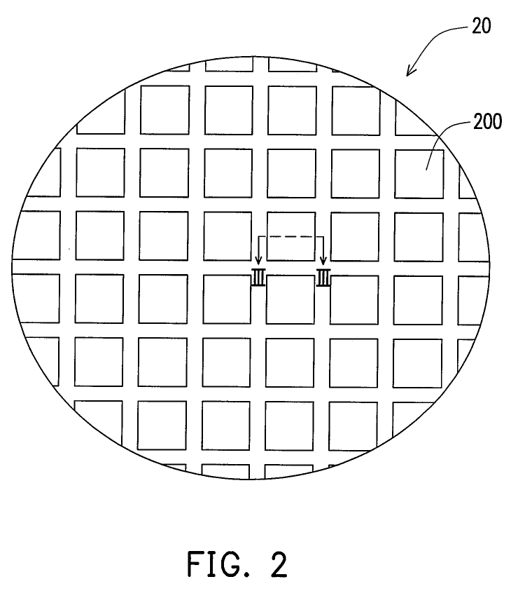

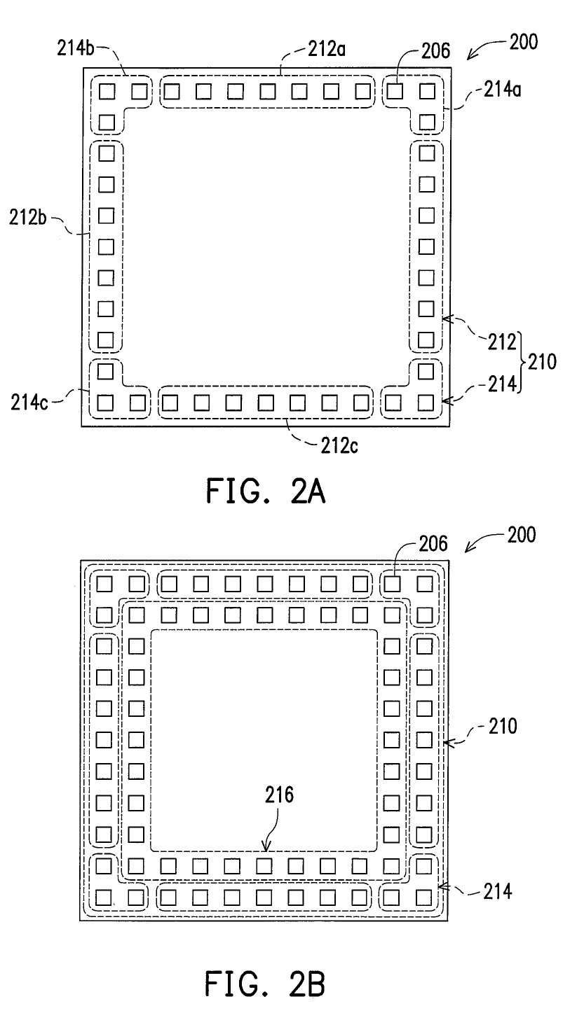

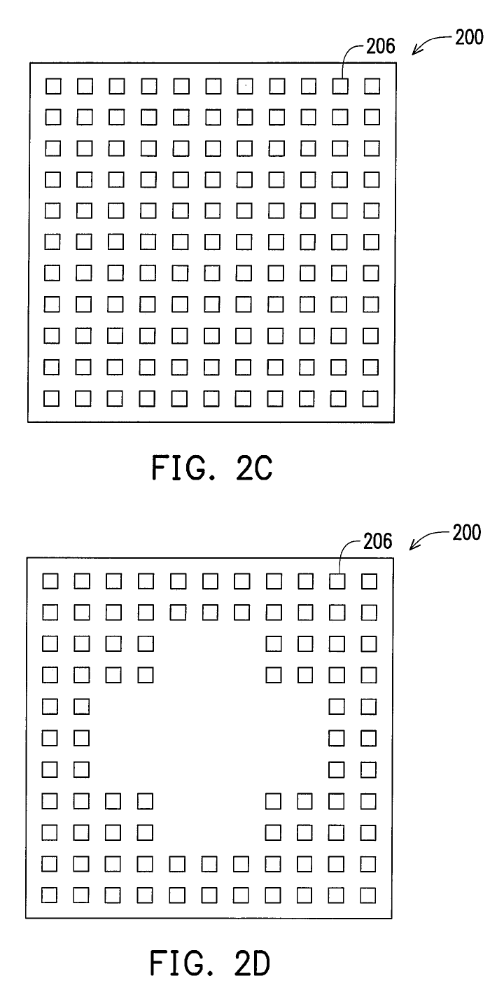

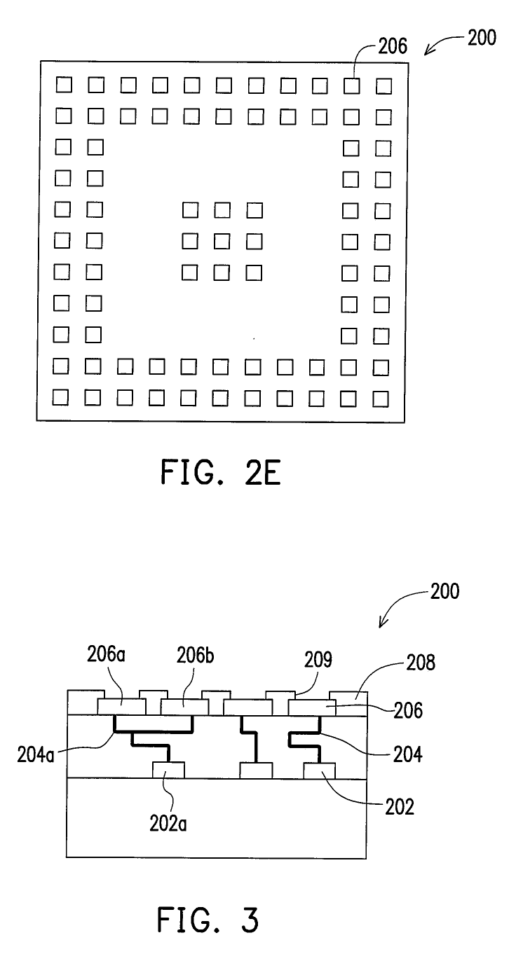

FIG. 2 is a schematic diagram illustrating a wafer according to an embodiment of the present invention. FIG. 3 is a schematic, cross-sectional view of FIG. 2 along the cutting line III-III.

Referring concurrently to FIGS. 2 and 3, the wafer 20 includes a plurality of chips 200. Each chip 200 includes a plurality of devices 202, metal interconnects 204, chip bump pads 206 and a passivation layer 208.

The material of the chip 200 may include silicon or semiconductor compound such as silicon germanium. The passivation layer 208 is the upper most layer on the wafer 20. The passivation layer 208 is formed with materials include but not limited to a combination of silicon oxide, boron phosphorous silicate glass (BPSG) or phosphorous silicate glass (PSG) and silicon nitride. The passivation layer 208 includes an opening 209 that exposes the chip bump pads 206. The material of the chip bump pads 206 includes but not limited to aluminum, such as aluminum-silicon alloy, aluminum-copper alloy or aluminum-silicon-copper alloy. The chip bump pads 206 are physically connected with the devices 202 via the metal interconnects 204.

The chip 200 in this embodiment includes two chip bump pads 206, for example, chip bump pads 206a and 206b which constitute one group of chip bump pads that are physically connected to a same device 202a via the underlying metal interconnects 204a. In the chip 200 of the present invention, the physically connected chip bump pads 206 are not limited to include two bump pads, but may include three bump pads. Further, the chip 200 of this embodiment is not limited to one group of the physically connected chip bump pads 206, but may include two groups, three groups or many groups of the physically connected chip bump pads 206. For the purpose of a simple illustration, the following disclosure is described in terms of a single group with two chip bump pads 206. However, this invention may be embodied in many different forms and should not be construed as limited to the embodiments set forth herein.

The electrically connected chip bump pads 206a and 206b can be any two chip bump pads of the chip bump pads 206 in the various arrangements. FIGS. 2A, 2B, 2C, 2D and 2E respectively illustrate the various arrangements of the chip bump pads 206.

Referring to FIG. 2A, in one embodiment, the chip bump pads 206 are disposed in the peripheral region 210. The peripheral region 210 includes a plurality of border regions 210 and a plurality of corner regions 212, for example. The two physically connected bump pads 206 may respectively disposed in the border regions 212, for example, in the border region 212a of the same side of or in the border regions 212a, 212b of different sides. The two physically connected chip bump pads 206 may respectively dispose in the corner region 214, for example, in the same corner region 214a or in different corner regions 214a, 214b. The two physically connected chip bump pads 206 may dispose respectively in the border region 212 and in the corner region, for example, in the border region 212a and the corner region 212a, or in the border region 212a and the corner region 212b.

Referring to FIG. 2B, in another embodiment, the chip bump pads 206 are disposed in the peripheral region 210 and the interior region 216 of the chip. The peripheral region 210 includes a plurality of border regions 212 and a plurality of corner regions 214. The physically connected two chip bump pads 206 may respectively dispose in the peripheral region 210, for example, both in the border region 212, both in the corner region 214 or in the border region and in the corner region 214, respectively. Moreover, the physically connected two chip bump pads 206 may respectively dispose in the interior region 216; or one chip bump pad 206 is disposed in the peripheral region 210, while the other chip bump pad 206 is disposed in the interior region 216.

As one of the two physically connected chip bump pads is configured at the corner 214, not only the reliability is enhanced, a function of structural protection is also provided. Particularly, when the four corners 214 respectively consists of two electrically connected chip bump pads 206, formation of crack or delamination at delicate parts of the chip can be effectively prevented.

Referring to FIG. 2C, in another embodiment, the chip bump pads 206 are arranged in an array on the surface of the chip 200. The physically connected two chip bump pads 206 in the array may be any two neighboring or distant bump pads 206.

FIGS. 2D and 2E respectively illustrate another two types of arrangement of the chip bump pads 206. The physically connected two chip bump pads may be any two of the neighboring or distinct bump pads 206.

It is appreciated that the arrangements of the chip bump pads 206 shown in FIGS. 2A, 2B, 2C, 2D and 2E introduced herein are presented by way of example and not by way of limitation. The arrangement for the physically connected chip bump pads may be in any form or shape in accordance to practical demands and requirement.

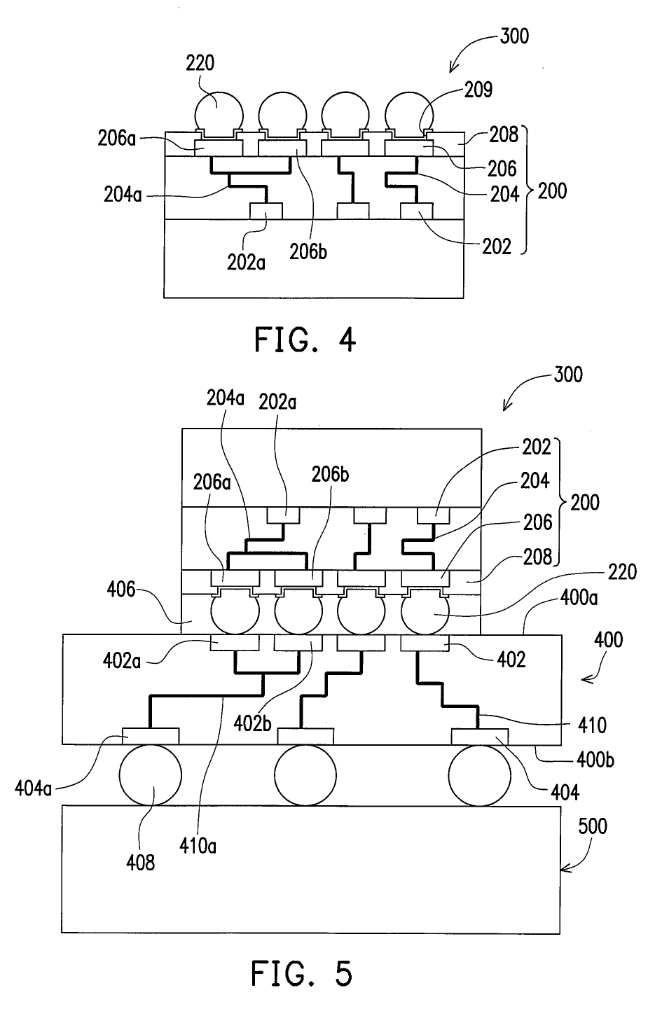

Thereafter, referring to FIG. 4, the Wafer Level CSP process is performed. A bump 220 is formed on each of the plurality of bump pads 206 on the wafer 20 (FIG. 3). The material of the bump 220 includes, for example, a tin-lead alloy. Thereafter, a wafer 20 dicing process is performed to form individual flip chip packages 300.

Thereafter, referring to FIG. 5, after forming the flip chip package 300, the flip chip package 300 is connected to a substrate 400. In an embodiment of the invention, the substrate 400 includes a plurality of bump pads 402 and a plurality of ball pads 404 which are respectively disposed on the upper surface 400a and the lower surface 400b of the substrate 400. The material that constitutes the bump pads 402 and the ball pads 404 includes, but not limited to, aluminum, such as aluminum-silicon alloy, aluminum-copper alloy or aluminum-silicon-copper alloy. A majority of the bump pads 402 is physically connected to one ball pad 404 through wiring 410. The two bump pads 402a, 402b of the bump pads 402 that are predetermined to be physically connected to the two chip bump pads 206a, 206b are physically connected to a same ball pad 404a through the wiring 410a in the substrate 400.

The flip chip package 300 is then connected the substrate 400 subsequent to a reflow process. During the reflow process, flux may apply. Subsequent to the reflow process, the bump 300 of the flip chip package 300 is connected to the bump pad 402 of the substrate 400. Thereafter, the space between the flip chip package 300 and the substrate 400 is filled with an underfill 406 to enclose the bumps 220.

Thereafter, a plurality of balls 408 is planted on the ball pads. After a reflow process, the substrate 400 is physically connected to the printed circuit board 500 through the balls. The material of the balls 408 includes, for example, tin-lead alloy or gold.

The device in the chip is physically connected to the substrate through two more of the bump pads and two or more of the bumps. Hence, even one pair of the bump and the chip bump pad fails to be physically connected, the chip may be physically connected to the same device via another pair of the bump and bump pad. Chances that the device is not electrically connected with the substrate through the bump due to a failure of electrical connection between a single bump and a single bump pad are greatly mitigated. Ultimately, the reliability of the final product is enhanced.

Further, since deices in the chip may be physically connected with the substrate through two or more pads and two or more bumps, the heat dissipation effect is better.

Moreover, when four corners of the chip respectively consist of the physically connected two chip bump pads, not only the reliability is effectively improved, formation of cracks or delimination at delicate parts of the chip can be obviated.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A semiconductor chip comprising:
a chip; and
a plurality of chip bump pads disposed on the chip, wherein the chip bump pads comprise at least two physically connected chip bump pads.

2. The semiconductor chip of claim 1, wherein the chip bump pads comprise a plurality of first chip bump pads configured in a peripheral region.

3. The semiconductor chip of claim 2, wherein the at least two physically chip bump pads includes at least two of the first chip bump pads.

4. The semiconductor chip of claim 3, wherein the peripheral region includes a plurality of border regions and a plurality of corner regions, wherein the above two physically connected chip bump pads are disposed in the border regions, the corner regions or respectively disposed in one of the border regions and in one of the corner regions.

5. The semiconductor chip of claim 1, wherein the chip bump pads comprise:
a plurality of first chip bump pads, disposed in a peripheral region of the chip;
a plurality of second chip bump pads, disposed in an interior region of the chip.

6. The semiconductor chip of claim 5, wherein the at least two physically chip bump pads includes at least two of the first chip bump pads.

7. The semiconductor chip of claim 6, wherein the peripheral region includes a plurality of border regions and a plurality of corner regions, wherein the above physically connected two first chip bump pads are configured in the border regions, in the corner regions, or respectively disposed in one of the border regions and in one of the corner regions.

8. The semiconductor chip of claim 5, wherein the at least two physically connected chip bump pads include at least two of the second chip bump pads.

9. The semiconductor chip of claim 5, wherein the at least two physically connected chip bump pads include at least one of the first chip bump pads and one of the second chip bump pads.

10. The semiconductor chip of claim 1, wherein the chip bump pads are arranged in an array.

11. The semiconductor chip of claim 1, wherein the chip bump pads comprise three physically connected chip bump pads.

12. The semiconductor chip of claim 1, wherein the chip bump pads comprise more than three physically connected chip bump pads.

13. The semiconductor chip of claim 1, wherein the chip bump pads comprises a plurality of physically connected chip bump pads.

14. The semiconductor chip of claim 1 comprises a plurality of metal interconnects, physically connected to the chip bump pads respectively, wherein the two physically connected chip bump pads are physically connected via one of the metal interconnects.

15. A package process comprising:
providing a flip chip package that comprises a chip and a plurality of bumps, wherein the chip comprises a plurality of chip bump pads thereon, and the chip bump pads comprises at least two physically connected chip bump pads, and the bumps are disposed on the chip bump pads;
providing a substrate that comprises a plurality of bump pads on a first surface of the substrate and a plurality of ball pads on a second surface of the substrate; and
physically connected the bumps of the flip chip package with portions of the bump pads of the substrate, wherein the two bump pads, which correspond to the two physically connected chip bump pads, on the substrate are physically connected to one of the ball pads.

16. The package process of claim 15 comprises a Wafer Level chip scale package (CSP) process.

17. The package process of claim 16, wherein the Wafer Level chip scale package process comprises:
providing a wafer, wherein the wafer comprises a plurality of chips, and each chip comprises a plurality of chip bump pads, and the chip bump pads comprises at least two physically connected chip bump pads;
forming the bumps on the chip bump pads of the wafer; and
dicing the wafer into a plurality of flip chip packages.

18. The package process of claim 15, wherein the two electrically connected chip bump pads are electrically connected to the bump pads underneath via a plurality of metal interconnects.

19. The package process of claim 16, wherein the two bump pads, corresponding to the two physically connected chip bump pads, on the substrate are physically connected to one of the ball pads, and the two bump pads on the substrate are physically connected to the ball pads via one wiring.

20. The package process of claim 15 further comprising:
forming a plurality of balls on the ball pads; and
connecting physically the substrate to a printed circuit board through the balls.
